(19) United States
(12) Patent Application Publication
(10) Pub. No.: US 2026/0036614 A1
(43) Pub. Date: Feb. 5, 2026

(54) SYSTEM AND METHOD TO GRADE AN ELECTRICAL COMPONENT FOR REUSE

(71) Applicant: JOSEPH MICHAEL SIEGER Trust, Barrington, IL (US)

(72) Inventor: Joseph Michael Sieger, Carrollton, TX (US)

(21) Appl. No.: 19/214,671

(22) Filed: May 21, 2025

Related U.S. Application Data
(60) Provisional application No. 63/677,488, filed on Jul. 31, 2024.

(51) Int. Cl. G01R 31/00; B60S 5/00; G01M 17/007; G06Q 10/20; G06Q 10/30; G07C 5/08

(52) U.S. Cl. CPC G01R 31/007; G01M 17/007; G06Q 10/20; G06Q 10/30; G07C 5/0816; B60S 5/00

(57) ABSTRACT

Briefly, one or more embodiments are direct to a process, system, and article for determining the reusability of one or more electrical components of a motor vehicle. The process may include receiving a diagnostic scan report for the motor vehicle, the diagnostic scan report indicating which motor vehicle systems or modules responded to a diagnostic scan request and any diagnostic trouble codes identified for any of the motor vehicle systems or modules. Diagnostic procedures may be obtained from a diagnostic procedures database. A reusability determination server may determine a reusability grade for the at least a first electrical component of the motor vehicle based on the diagnostic scan report and the diagnostic procedures, the determining including assigning first relative weights to information from the diagnostic scan report and the diagnostic procedures.

### CROSS-REFERENCE TO RELATED APPLICATIONS

The present application claims the benefit of U.S. Provisional Patent Application No. 63/677,488, entitled “METHOD TO GRADE AN ELECTRICAL COMPONENT FOR REUSE” and filed on Jul. 31, 2024. The entire content of that application is incorporated herein by reference.

### BACKGROUND

There are a number of ways in which to obtain or otherwise acquire electrical components for use within a vehicle. One way in which to obtain such electrical components is by ordering a new electrical component from the manufacturer. However, if the electrical component is specialized, the manufacturer may not have the electrical component in stock for shipping to a buyer until the electrical component can be specially manufactured. Moreover, if the manufacturer is located in certain foreign countries or jurisdictions, a buyer may be at the mercy of a supply chain which may be subject to various disruptions, such as shipping delays or delays while the electrical component waits to go through customs, for example.

Another way to obtain electrical components for a vehicle is by removing the electrical components from existing vehicles and then reusing the electrical components in a different vehicle. For example, if a vehicle has been in an accident or is otherwise damaged, the owner of the vehicle typically takes the vehicle to a workshop, such as an autobody shop, automobile dealer, or some other entity which handles or performs repairs as needed. In some instances, the automobile is capable of being repaired, but in other instances, the cost of repairing the automobile is prohibitively expensive, in which case the automobile may be scraped or sold for its parts. For example, even if the automobile suffers extensive damage to its chassis during a traffic accident, some of the electrical components or other components within the automobile may still be in working condition and may be removed and reused in a different automobile.

However, even if various electrical components are removed, such as via a dismantling or disassembly process, from an automobile which has been in an accident, there may not be an easy way of determining the reusability of electrical components within the vehicle. For example, if the automobile has been rear-ended and suffered extensive damage to the rear of the automobile, even if the cost of repairing the automobile is prohibitively expensive, there may still be usable components located within the front portion of the automobile, such as within the dashboard or engine. However, unless a technician manually inspects the automobile and performs various manual tests on electrical components of the automobile, a process which may be relatively time-consuming, there may not be a way of readily determining the reusability of any of the electrical components of the automobile.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 illustrates an embodiment of some entities involved in vehicle repair and salvage.

FIG. 2 illustrates an OBD2 (On-Board Diagnostics II) scanner according to an embodiment.

FIG. 3 illustrates an embodiment of a system for performing a diagnostic scan of a vehicle and determining the reusability of one or more electrical components or modules of vehicle.

FIGS. 4A and 4B collectively illustrate an embodiment of a first portion and a second portion of a diagnostic scan report of a vehicle.

FIGS. 5-7B illustrate embodiments of a portion of a diagnostic procedure for particular diagnostic trouble codes (“DTCs”).

FIG. 8 illustrates an embodiment of a system for determining the reusability of one or more electrical components or modules of a vehicle.

FIG. 9 illustrates an embodiment of a flow diagram for grading the reusability of one or more electrical components for a motor vehicle.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein.

One or more embodiments, as discussed herein, are directed to a system and process for determining the reusability of one or more electrical components of an automobile or other vehicle. The terms “vehicle,” “motor vehicle,” and “automobile” are used interchangeably herein. “Reusability” for an electrical component, as used herein, refers to an ability of the electrical component to be used again or repeatedly in its original or modified form, after its initial intended purpose, without requiring significant reprocessing or degradation of functionality. For example, an electrical component which is reusable may be removed or disassembled from one automobile and installed for use on a different automobile.

Some vehicles may be involved in accidents or may otherwise be damaged but may never be repaired because, for example, it may be cost-prohibitive to repair a particular vehicle which has an extensive amount of damage. Instead, such a vehicle may have parts or components which are still in working condition and which be harvested for reuse in another vehicle or elsewhere. However, in order to determine whether a part or component is suitable for reusable, certain tests or inspections may be performed before determining whether the part or component should be harvested from a vehicle for reuse in another vehicle. One or more embodiments, as discussed herein, provide a method for determining whether an electrical component is in working condition—and thus reusable in a second vehicle—without investing the time and labor to repair the first vehicle. Such a method may, for example, determine and/or grade the reusability of a particular electrical component of a vehicle based on various sources of information to infer a reusability of the electrical component.

There are many different sources of information which may be used to determine or otherwise infer the reusability of a particular electrical component of a vehicle. Various sources of information may include, for example, results of a diagnostic scan performed on the vehicle and any corresponding diagnostic trouble codes indicated on a report of the diagnostic test; photographs of the vehicle, such as photographs of damage to the vehicle if the vehicle has been in an accident, or photographs of the dashboard of the vehicle showing any visual warnings to a driver of the vehicle; information about a seller of the vehicle, such as whether the seller is an insurance company or some other reputable owner likely to have kept the vehicle in relatively good condition, to name just a few examples among many.

If a vehicle has been damaged, the vehicle may be inspected by a repair shop to determine what repairs should be made to the vehicle, after which an owner of the vehicle may decide to either repair the vehicle or, if it would not be economically feasible to repair the vehicle, a determination may be made to sell the vehicle to a buyer, such as a disassembler, who may remove usable parts or components from the vehicle for resale or use in other vehicles. However, instead of repairing the vehicle, the results of the inspection may be used to determine the reusability of various parts of the vehicle, such as of electrical components.

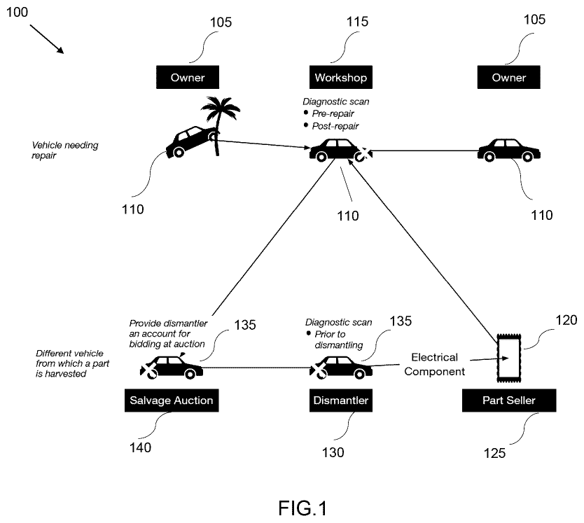

FIG. 1 illustrates an embodiment 100 of some entities involved in vehicle repair and salvage. As shown, an owner 105 of a first vehicle 110 may be involved in an accident or may have some other type of loss event after which the first vehicle 110 is in need of repair. A workshop 115 may be given custody of the first vehicle to determine whether the first vehicle 110 is capable of being repaired. For example, the owner 105 may either drive the first vehicle 110 to a workshop 115 or the first vehicle 110 may be towed to the workshop or end up at the workshop 115 some other way. A technician at the workshop 115 may perform a pre-repair diagnostic scan of the first vehicle 110 to determine what components and/or systems of the first vehicle are damaged or otherwise in need of repair or replacement. A diagnostic scan on a vehicle may be performed by connecting a specialized tool, called an OBD2 (On-Board Diagnostics II) scanner, to the vehicle's Diagnostic Link Connector (DLC) which allows access to the car's computer or OBD system. A DLC comprises a multi-pin diagnostic connection port for automobiles, trucks, and motorcycles used to interface an OBD2 scanner with the control modules of a given vehicle and access on-board diagnostics and live data streams. A DLC is often located under the instrument panel on the driver's side. The instrument panel is a portion of the dashboard which sits behind the steering wheel of first vehicle 110. The instrument panel comprises a control panel that displays information about the first vehicle's 110 status and performance.

OBD is a system that monitors the first vehicle's 110 computer system and reports diagnostic trouble codes. A “diagnostic trouble code” or “DTC,” as used herein, refers to a code generated by a vehicle's OBD system to indicate a specific problem, helping pinpoint the location and nature of a malfunction. Diagnostic trouble codes are designed to alert vehicle owners and mechanics to potential issues with the vehicle's systems. When a vehicle's OBD system detects a malfunction, it may generate an appropriate diagnostic trouble code and may send an alert to the owner of the vehicle via a light or other indicator on an instrument panel of the vehicle.

If an automobile is brought to a workshop for potential repairs, a workman may connect an OBD2 scanner to the vehicle's DLC to prompt the vehicle's OBD system to perform various tests. For example, the OBD2 scanner may prompt the OBD system to ping or contact every control system in the first vehicle 110 to determine whether any of the control systems or electrical components exist or are malfunctioning. In the event that one or more of the control systems or electrical components is not functioning properly, a trouble code for a faulty control system or faulty electronic component may be transmitted to the OBD2 scanner so that the trouble code may be displayed to a workman.

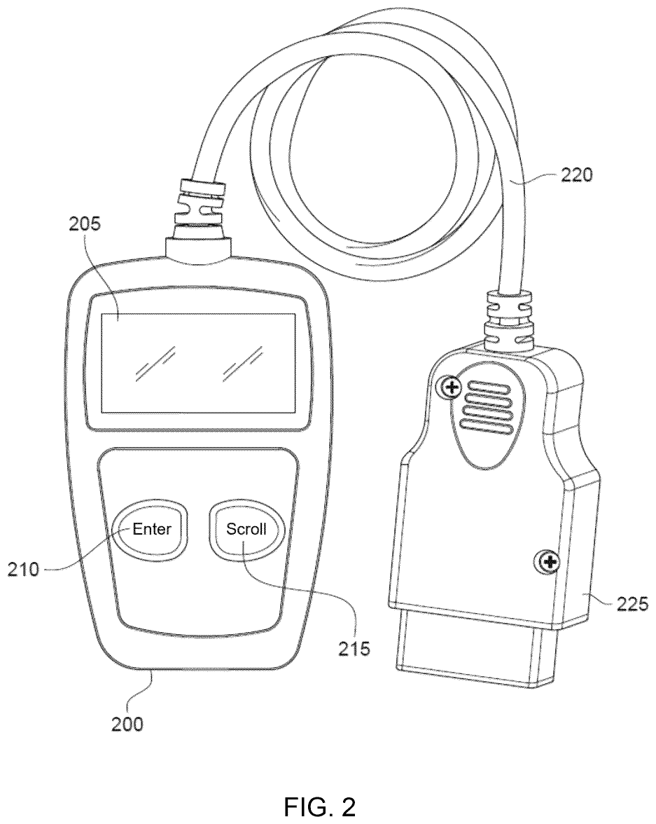

FIG. 2 illustrates an OBD2 scanner 200 according to an embodiment. As shown, OBD2 scanner 200 may comprise a handheld mobile device which includes a display 205, one or more input buttons or keys, such as enter button 210 and a scroll button 215, to name two examples of buttons or keys on an OBD2 scanner. In some embodiments, OBD2 scanner 200 may include a keypad or may be capable of being coupled to a keypad, keyboard, and/or some other user input device to receive user inputs. OBD2 scanner 200 may include or be coupled to a plug 225 via a cord 220. Plug 225 may be detachable connected to a vehicle's DLC to initiate a diagnostic scan and/or to receive the results of such a diagnostic scan of the vehicle. For example, if there are any detected faulty components of a control system or electrical components of the vehicle, one or more diagnostic trouble codes may be presented to a technician via display 205. In some embodiments, an explanation for each detected trouble code may also be presented on display 205.

An ODB scanner 200 may obtain an identifier of the first vehicle 110 when connected to the vehicle's DLC. The OBD2 scanner 200 may also determine all of the modules of the first vehicle 110. A “module,” as used herein, refers to an electrical component, computing device, or computer that controls a specific function or set of functions in a vehicle. New cars often have more than 30 different modules within them. Examples of commonly used modules include an engine control module which manages the vehicle's engine's performance by monitoring sensors and adjusting fuel injection, ignition timing, and other functions. A transmission control module may manage shifting, particularly in automatic transmissions. A powertrain control module may combine the functions of the engine control module and transmission control module into one unit. A brake control module may control a vehicle's wheels and braking system. A door control unit module may control the doors of the vehicle. An electric power steering control unit module may control an electric power steering system of the vehicle. A human-machine interface module may enable a human operator to interact with a machine or system of the vehicle. A seat control unit module may control the seats of the vehicle. A speed control unit module may control the speed of the vehicle. A telematic control unit module may manage telematics services, essentially acting as a communication hub to collect, process, and transmit data about the vehicle's location, performance, and driver behavior to external systems, enabling features like vehicle tracking, emergency call systems, and driving analysis. A battery management system module may monitor the state and health of one or more batteries of the vehicle.

Referring back to FIG. 1, after performing a pre-repair diagnostic scan, the results of the scan may be presented to a technician at workshop 115. For example, an ODB scanner 200 may read data from various sensors and components to identify any malfunctions or error codes, essentially providing a detailed analysis of the car's health and pinpointing potential problems by interpreting the stored codes displayed on a display of ODB scanner. Results of the diagnostic scan may include learning the identification number of an electrical component 120 in a circuit or system or a diagnostic trouble code from a damaged or faulty circuit or system. After performing the pre-repair diagnostic scan, the workshop 115 may provide results of the diagnostic scan to owner 105 and may inform the owner 105 whether the first vehicle 110 should be repaired, or whether the extent of damage to first vehicle 110 is so great that repair would be prohibitively expensive. In the event that a decision is made to repair the first vehicle 110, the workshop 115 may contact a part seller 125 to obtain or otherwise order the replacement electrical component for use in the first vehicle 110. Part seller 125 may maintain an inventory of vehicle parts which have been harvested from or otherwise acquired by a dismantler 130. A dismantler 130 may comprise a component or other entity which purchases vehicles, such as a second vehicle 135 from a salvage auction 140. Many vehicles use specialized electronic components which may not be readily available in brand new condition. For example, there may be a controller which is only used within BMW™ vehicles of a particular model sold in a particular year and which may not currently be manufactured. In some instances, the controller may still be manufactured, but as a result of supply chain disruptions, a new replacement controller may not be available for an extended period of time, potentially months. Moreover, if the controller is only manufactured overseas, there may also be delays introduced while shipments of replacement controllers wait to go through Customs inspections at a port of entry, for example. Accordingly, instead of waiting for a potentially extended period of time for a newly manufactured replacement controller to be received for replacement of a damaged component, a replacement controller which has been in use and still has a serviceable lifespan may instead be acquired from an existing vehicle. For example, if a vehicle has incurred extensive damage to a body or engine but diagnostic tests reveal that at least some of the electrical or electronic components of the vehicle are still functioning properly, such electronic components may be harvested from the damaged vehicle and used as replacement electronic components for a different vehicle which is being repaired. In the embodiment shown in FIG. 1, dismantler 130 may run a diagnostic scan on second vehicle 135 after purchasing or otherwise acquiring the second vehicle 135 from the salvage auction 140. The diagnostic test may be performed to learn the identification number of an electrical component in a circuit or system or to learn there the circuit or system has no diagnostic trouble code indicating the electrical component might not work Dismantler 130 may maintain an inventory of serviceable components harvested from second vehicle 135 as well as from other vehicles purchased from salvage auction 140 or otherwise acquired some other way. Dismantler 130 may sell electrical component 120 to part seller 125 and part seller 125 may, in turn, sell electrical component 120 to workshop 115 to replace a damaged electrical component of first vehicle 110. After workshop 115 repairs first vehicle 110 by replacing the damaged electrical component with the electrical component 120 acquired from part seller 125, the workshop 115 may perform a post-repair diagnostic scan to confirm the repair before custody of the vehicle is given to the owner 105. In some embodiments, a single entity may comprise both the dismantler 110 and the part seller 125.

Although the results of the diagnostic scan of first vehicle 110 may be performed to determine diagnostic trouble codes for malfunctioning electrical components or modules to determine whether those electrical components or modules should be replaced, the results of the diagnostic scan may additionally be utilized to infer or otherwise determine which electrical components may be in working condition, such as for harvesting and reuse in a different vehicle. For example, the diagnostic scan may list a variety of different electrical modules or components of the vehicle which were pinged during a diagnostic scan. The diagnostic scan may indicate identifiers for each of the pinged electrical modules or components as well as DTCs determined for any of the pinged electrical modules or components. If, for example, a particular electrical component or module was pinged but did not respond, it may be inferred that the non-responsive electrical modules or components are likely not in working or reusable condition. However, if a pinged electrical module or component did respond to the ping but did not identify any DTCs, it may be inferred that the responding electrical module or component is likely in working and reusable condition. However, if a DTC is returned for a pinged electrical module or component, then additional sources of information may be used to determine or grade the reusability of the electrical module or component, as discussed in further detail below.

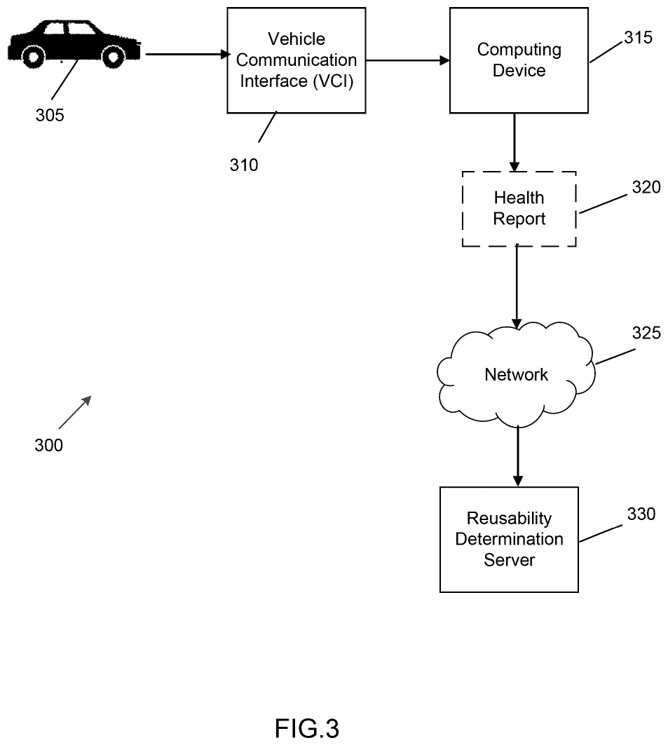

FIG. 3 illustrates an embodiment 300 of a system for performing a diagnostic scan of a vehicle 305 and determining the reusability of one or more electrical components or modules of vehicle 305. As illustrated, a diagnostic scan may be performed on vehicle 305. For example, a laptop computer 315 may include or have installed thereon a software application for initiating a diagnostic scan or diagnostic tests on vehicle 305, in a manner similar to OBD2 scanner 200 as shown in FIG. 2. Laptop computer 315 may have software installed thereon licensed from a manufacturer of vehicle 305. Laptop computer 315 may interface with a DLC of vehicle 305 via a Vehicle Communication Interface (VCI) 310. A VCI 310, as used herein, refers to a hardware component which allows a vehicle's electronic control units (ECUs) to communicate with external devices and diagnostic applications. An “ECU,” as used herein, refers to a typically small, computerized or electrical component that manages one or more systems within a vehicle by receiving data from sensors or other ECUs throughout the vehicle, processing the data, and then sending signals to actuators to adjust different functions, essentially acting as the “brain” of a modern automobile, controlling everything from engine performance and transmission to safety features like airbags and even comfort features such as power windows and climate control.

VCI 310 may plug into an OBD2 port of vehicle 305 on one end, and the other end may be coupled to laptop computer 315, such as through wired connection or through a wireless connection, such as BlueTooth™. Through use of VCI 310, an application running on laptop computer 315 may initiate a diagnostic scan of vehicle 305 and may generate a diagnostic scan report 320 about the health of the vehicle's 305 circuits and systems. The report 320 may be presented on laptop computer 315, such as within a web browser. In embodiment 300, when a technician utilizes laptop computer 315 to initiate a diagnostic scan of vehicle 305, a report 320 containing results of the diagnostic scan may be displayed within a web browser presented on a graphical user interface of laptop computer 315. For example, the report 320 of the results of the diagnostic scan may be stored locally on laptop computer 315.

In accordance with a particular embodiment, the application used to initiate the diagnostic scan may receive the results of the diagnostic scan from the VCI 310. In one implementation, the application may generate the report 320 which includes the results of the diagnostic scan, and that report 320 may be stored as a file in a storage location of the laptop computer 315, such as in a temporary storage area. The report 320 may be transmitted, such as by an application running on laptop computer 315, to a reusability determination server 330 via a network 325, such as the Internet. Reusability determination server 330 may process the report 320 as well as other information known about vehicle 305, such as photographs of the vehicle 305, an identity of an owner of the vehicle 305, and/or known diagnostic procedures for addressing any diagnostic trouble codes indicated in the report, to name just a few examples of information, for example, in order to infer or otherwise determine and grade the reusability of one or more electrical components or modules of the vehicle 305. After determining or grading the reusability of one or more electrical components or modules, reusability determination server 330 may store the determination or grade of the reusability as well as an identifier for the corresponding electrical component or module. Reusability determination server 330 may additionally transmit the determination or grade of the reusability of the one or more electrical components or modules back to laptop computer 315 for display, for example. In some embodiments, the determinations of reusability of various electrical components or modules may be accessible and used to provide responses to queries of reusability determination server 330, for example.

It should be appreciated the diagnostic scan of vehicle 305 may be initiated by a workshop determining whether to repair vehicle 305, prior to initiating such repairs. The diagnostics scan may also, or alternatively, be initiated by a dismantler who has obtained vehicle 305 from a salvage auction. Regardless of which entity initiates the diagnostic scan, the report 325 may be transmitted to reusability determination server 330.

If vehicle 305 has been damaged to the extent that it would not be cost-effective to repair the vehicle 305, the vehicle 305 may be sold to an auto parts dismantler. For example, if the damaged vehicle 305 is insured by an insurance company, the owner of the damaged vehicle 305 may file a claim for the damage with his or her insurance company. The insurance company may inspect the vehicle 305 to determine the extent of damage, such as through the use of a workshop where a technician may run diagnostic tests on the vehicle 305 to determine which control or electrical systems are damaged within the vehicle 305. If the insurance company decides that the vehicle 305 is not worth repairing, the insurance company may pay out the claim to the holder of insurance for the vehicle 305 and may take possession of the damaged vehicle 305. The insurance company may thereafter sell the vehicle 305 to a third party, such as at a salvage auction. For example, damaged automobiles are often purchased at salvage auctions for their parts, such as for items on the body of the vehicle 305, including hoods, doors, bumpers, gas tanks, and various internal circuitry for control systems of the automobile, to name just a few examples among many. After a third party, such as a dismantler, purchases the automobile at a salvage auction, the dismantler may run diagnostic scans of control systems of the vehicle to determine which electronic components of the automobile are functioning properly and may be used in other automobiles, for example.

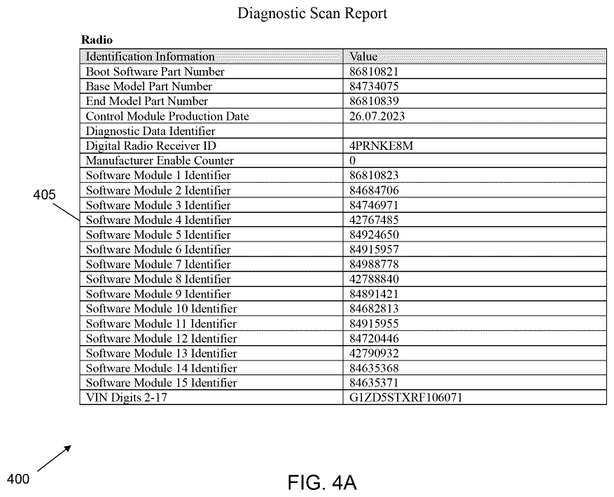

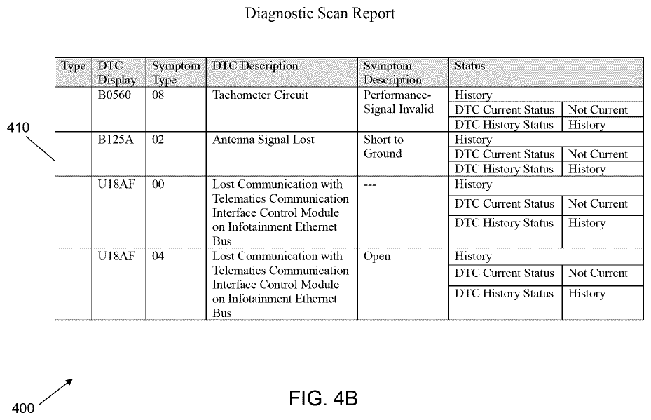

FIGS. 4A and 4B collectively illustrate an embodiment 400 of a first portion 405 and a second portion 410 of a diagnostic scan report of a vehicle. Embodiment 400 illustrates various information of a diagnostic scan report which relates to a radio control unit of a vehicle. For example, the information shown in embodiment 400 of FIGS. 4A and 4B may be determined by running a diagnostic scan of a vehicle, such as through the use of ODB2 scanner 200 of FIG. 2. The diagnostic scan report may include various items of “identification information” and corresponding values, such as identifier values. As shown, “Boot Software Part Number” may be associated with value, “86810821.” “Base Model Part Number” may be associated with value, “84734075.” “End Model Part Number” may be associated with value, “86810839.” “Control Module Production Date” may be associated with value, “26.07.2023.” “Diagnostic Data Identifier” may not be associated any value in embodiment 400. “Digital Radio Receiver ID” may be associated with value, “4PRNKE8M.” “Manufacturer Enable Counter” may be associated with value, “0.” “Software Module 1 Identifier” may be associated with value, “86810823.” “Software Module 2 Identifier” may be associated with value, “84684706.” “Software Module 3 Identifier” may be associated with value, “84746971.” “Software Module 4Identifier” may be associated with value, “42767485.” “Software Module 5 Identifier” may be associated with value, “84924650.” “Software Module 6 Identifier” may be associated with value, “84915957.” “Software Module 7 Identifier” may be associated with value, “84988778.” “Software Module 8 Identifier” may be associated with value, “42788840.” “Software Module 9Identifier” may be associated with value, “84891421.” “Software Module 10 Identifier” may be associated with value, “84682813.” “Software Module 11 Identifier” may be associated with value, “84915955.” “Software Module 12 Identifier” may be associated with value, “84720446.” “Software Module 13 Identifier” may be associated with value, “42790932.” “Software Module 14 Identifier” may be associated with value, “84635368.” “Software Module 15 Identifier” may be associated with value, “84635371.” “VIN Digits 2-17” may be associated with value, “GIZD5STXRF106071.”

The diagnostic scan report may list additional information showing diagnostic trouble codes (“DTCs”) for the radio control unit. For example, DTC “B0560” may be associated with symptom byte “08,” corresponding DTC Description “Tachometer Circuit,” and symptom description, “Performance-Signal Invalid.” A “symptom byte,” as used herein, refers to a two-character hexadecimal code appended to a DTC to provide more specific information about the nature of the fault, aiding in quicker and more accurate diagnosis.

The diagnostic scan report additionally indicates that DTC “B125A” may be associated with symptom byte “02,” corresponding DTC Description “Antenna Signal Circuit,” and symptom description, “Short to Ground.” DTC “U18AF” may be associated with symptom byte “00,” corresponding DTC Description “Lost Communication with Telematics Communication Interface Control Module on Infotainment Ethernet Bus,” and, in this case there may not be a corresponding symptom description. DTC “U18AF” may be associated with symptom byte “04,” corresponding DTC Description “Lost Communication with Telematics Communication Interface Control Module on Infotainment Ethernet Bus,” and symptom description, “Open.”

As discussed above, the diagnostic scan report may be transmitted to a reusability determination server 330 to determine or infer or grade the reusability of one or more electrical components or modules of the vehicle.

Upon receiving the diagnostic scan report, reusability determination server 330 may determine which electrical components or modules are in a reusable condition. For example, there is one “Radio” having identifier End Model Part Number 86810839 and 15 different software module identifiers listed in the diagnostic scan report of embodiment 400. There are also four DTCs associated with a circuit or system that includes electrical components, wiring, and/or software, to name just a few items among many. The DTCs may be related to some of the 16 identifiers, but other of the identifiers may be unassociated with any of the DTCs. A DTC itself may be stored in a control module, such as “Radio”, for example. A DTC may relate to one of the 16 identifiers or it may relate to none of them, e.g., in some instances, the DTC may relate to an electrical component elsewhere in the circuit or system. Any of the identifiers which are not associated with any of the DTCs may be determined to be in reusable condition. However, if any of the DTCs are associated with any of the 16 identifiers are listed in the diagnostic scan report of embodiment 400, additional sources of information may be utilized to determine whether any of the associated software modules are likely reusable.

One potential source of information for inferring or determining the reusability of a particular electrical component or module is a diagnostic procedure relating to a DTC. For example, a vehicle manufacturer may have various protocols or procedures relating to various DTCs, such as one specific protocol for each DTC, for determining how to address an issue or malfunction which has caused the DTC. For example, there may be multiple different reasons for why a particular electrical component, module, or system is malfunctioning and a DTC, by itself, may not be able to directly identify how to address the underlying issue which has resulted in the generation of the DTC. In other words, a diagnostic scan report may display any DTC for a circuit or system. The presence of a DTC does not necessarily mean an electrical component has malfunctioned because, for example, a circuit or system comprises more than electrical components, such as wires, fuses, etc., any of which may malfunction. Such a circuit or system requires power, software configuration files, etc., all of which can malfunction.

Vehicle manufacturers may have specific diagnostic procedures or protocols for determining the underlying cause of the issue which resulted in the DTC. In accordance with an embodiment as discussed herein, instead of using diagnostic procedures to determine how to repair a component of a vehicle to address an issue causing generation of a DTC, the diagnostic procedures may instead be used to infer or deduce whether a particular electrical component or module is likely unrelated to the DTC, in which case the electrical component or module may still be working condition and graded for reuse, for example.

It should be appreciated that in some embodiments, an electrical component of a vehicle being dismantled may be reusable in certain vehicles but not be reusable in some other vehicles. For example, some vehicles which need a replacement electronic component may only be able to accept an electrical component from a dismantled vehicle if the electrical component has certain specified software modules. Accordingly, a reusability grade for a particular electrical component of the vehicle being dismantled may be at least partially based on at least one of a repair diagnostic scan or repair descriptive information for a secondary motor vehicle under repair. In other words, the reusability grade for the at least one electrical component may be at least partially based on the suitability of the particular electrical component in a secondary motor vehicle under repair which needs the particular electrical component in order to complete the repair. For example, a vehicle under repair may require the use of certain software modules which may or may not be employed within the particular electrical component of a vehicle being dismantled.

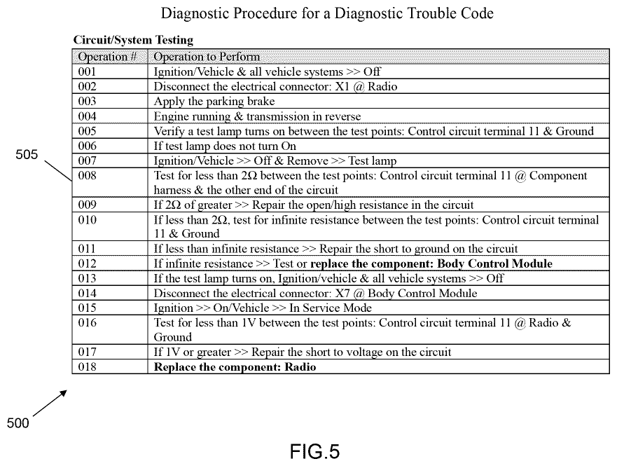

FIG. 5 illustrates an embodiment 500 of a portion of a diagnostic procedure 505 for a particular DTC. “Diagnostic procedure,” as used herein, refers to a series of operations or steps to be performed in a particular order to identify a cause of a DTC. For example, a diagnostic procedure may be performed in order to determine why a particular system or component has malfunctioned and what steps should be performed in order to address the underlying cause of the DTC, such as replacing or repairing a particular component or module. In some embodiments, the operations of a diagnostic procedure may be performed in a sequence until a determination is capable of being made as to one or more electrical components to be repaired or replaced in order to address the root cause of the DTC.

In the case where the vehicle is being repaired, one invests the time and labor to perform the tasks in the diagnostic procedure to determine which, if either, electrical component should be replaced. In the case where the vehicle will not be repaired (e.g., will be dismantled), one can use available information in addition to the diagnostic scan report (and any diagnostic trouble codes) and the diagnostic procedures to determine the reusability of each electrical component, e.g., grade each electrical component for reuse.

Diagnostic procedure 505 of embodiment 500 indicates various steps to be undertaken to determine the underlying cause of the DTC. For example, diagnostic procedure 505 indicates a series of steps or operations to be performed in a particular order. Diagnostic procedure 505 indicates that the ignition of a vehicle and all vehicle systems should be turned off and an electrical connector X1 at a radio should be disconnected. The diagnostic procedure 505 also indicates that a technician should apply the parking brake and run the engine and transmission in reverse.

Diagnostic procedure 505 indicates a number of additional steps to be undertaken to determine whether to replace a Body Control Module or a Radio. Accordingly, if a particular DTC is generated which is associated with diagnostic procedure 505, steps of the diagnostic procedure 505 may be performed which may result in replacement of the Body Control Module or the Radio. Therefore, even if the exact steps of diagnostic procedure 505 are not implemented, if one could access diagnostic procedure 505 for a particular DTC, one could know that only the Body Control Module or the Radio may be faulty and in need of replacement. Therefore, any other electrical components of a system associated with the DTC but which are not components of either the Body Control Module or the Radio may be considered to be unrelated to the DTC and an inference or determination may therefore be made that the other electrical components or modules are likely in working an reusable condition.

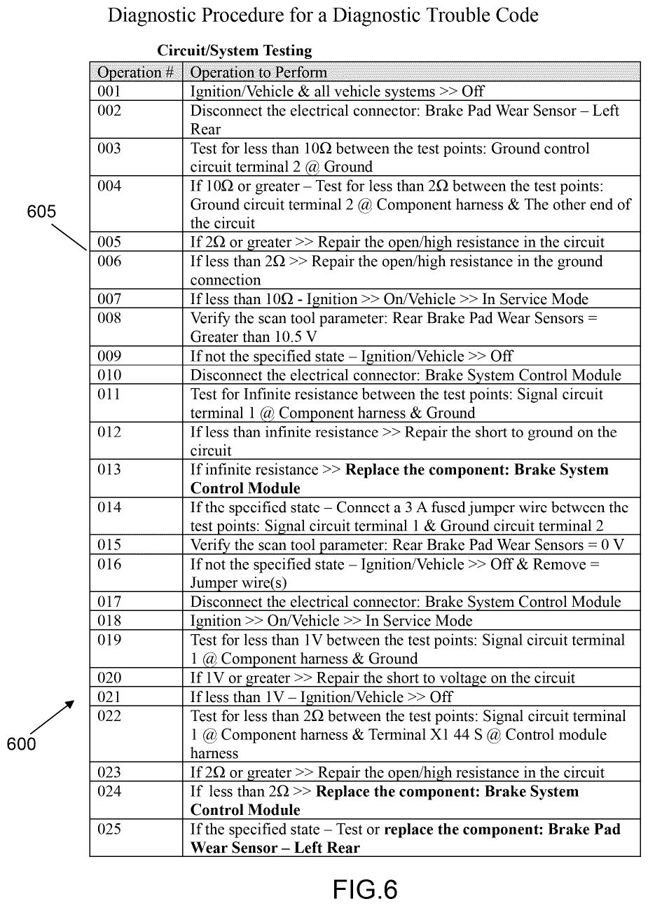

FIG. 6 illustrates an embodiment 600 of a portion of a diagnostic procedure 605 for a particular DTC. Diagnostic procedure 605 indicates a number of steps to be undertaken to determine whether to replace a Brake System Control Module or a Brake Pad Wear Sensor on the Left Rear wheel of the vehicle. As an example, the additional information available may be the location of damage on the motor vehicle. When a vehicle is deemed a total loss by an insurance company, the damage location may be categorized, e.g., “rear end”, “left rear”, etc. When the location of the damage (“rear end” or “left rear”) is not in the same location as the Brake System Control Module (“in the engine compartment, i.e., not the rear of the vehicle”) and is in the same location as the Brake Pad Wear Sensor (“under the left rear of the vehicle”), then one can determine the reusability of the Brake System Control Module in another motor vehicle. One may predict that the Brake Pad Wear Sensor is more likely to be damaged than the Brake System Control Module. Moreover, one may predict the Brake Pad Ware Sensor alone is more likely to be damaged than both the Brake Pad Wear Sensor and the Brake System Control Module because the source of this vehicle is an insurance company with a collision total loss, increasing the probability the Brake System Control Module was operational before the collision event.

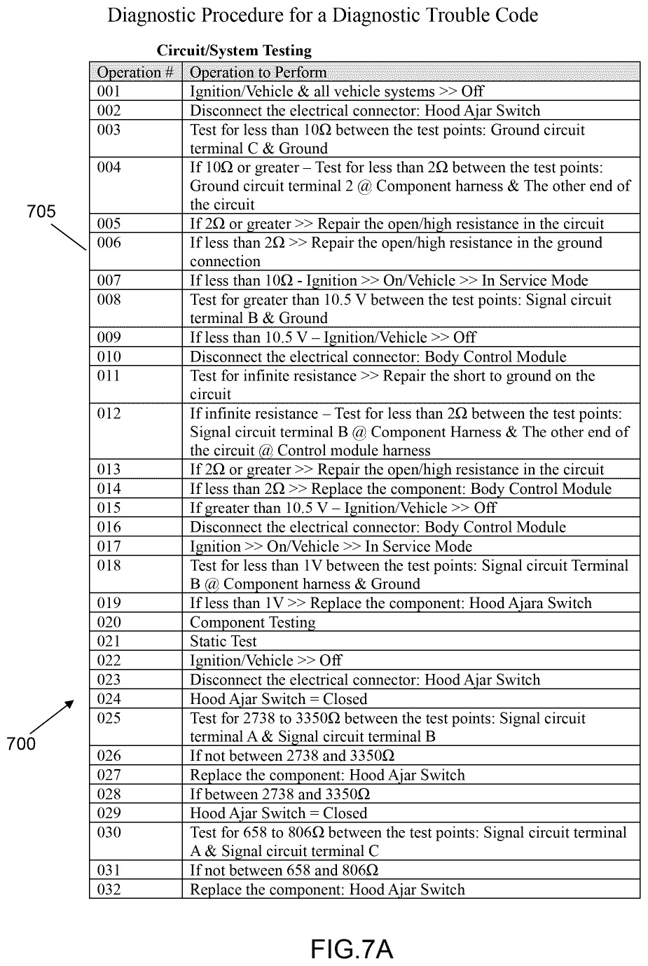

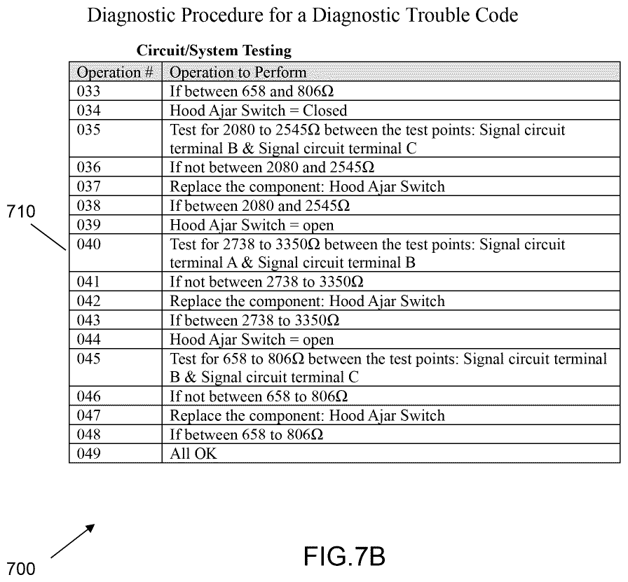

FIGS. 7A and 7B collectively illustrate an embodiment 700 of a first portion 705 and a second portion 710 of a diagnostic procedure for a particular DTC. The diagnostic procedure of embodiment 700 indicates a number of steps of be undertaken where if certain information is known about the particular circumstances of the vehicle, a decision may be made as to whether either the Body Control Module or the Hood Ajar Switch are likely in working and reusable condition, or whether either of these items should instead be replaced. For example, if the vehicle is known or predicted to receive electrical power from an external source, it may be inferred that the hood is necessarily open in order to receive the electrical power. Accordingly, because the hood is open, a DTC for the Hood Ajar Circuit may be generated. The diagnostic procedure of embodiment 700 for this particular DTC potentially instructs the replacement of the Body Control Module or the Hood Ajar Switch. However, if the vehicle's particular circumstance of having the hood open is known, one may predict or infer that the DTC is more likely a result of the hood being open than a damaged Body Control Module. Moreover, if additional information is known about the vehicle, such as if the source of this vehicle is an insurance company with a collision total loss, it may be inferred that there is a relatively high probability the Body Control Module was operational before the collision event because, for example, an entity who paid to insure the vehicle would be more likely to file a claim with an insurance company to keep the vehicle in working condition with a fully functional Body Control Module prior to the collision event.

Another example of the additional information available for determining the reusability of an electrical component or module is knowledge about a vehicle's current or previous owner, loss type, damage type, or physical event that occurred having potential of loss or harm to vehicle. When a loss type or damage type for a vehicle is “flood” (as opposed to collision or theft, for example), one might mitigate the risk an electrical component anywhere in the vehicle was exposed to water by assuming that every electrical component in the vehicle was exposed to water when determining its reusability.

Other information for determining the reusability of an electrical component or module of a vehicle may include knowledge about the vehicle's chain of custody or knowledge about the amount of time between when a diagnostic scan was performed or a loss event occurred and when the reusability of an electrical component was determined. If, for example, a vehicle is a total loss from an insurance company, the vehicle may be sold at a salvage automotive auction, in which case there may be documentation of the chain of custody of the vehicle leading to the high bidder at the auction. When there is a documented chain of custody, the reusability of an electrical component is likely to be greater than the reusability would be if there is not a known chain of custody because there is greater accountability in the event an electrical component is not as expected. Similarly, when the amount of time leading to the reusability being determined is shorter, the reusability of an electrical component is greater because there is less time for an electrical component to start operating in an unexpected manner.

Another potential type of information for determining reusability of an electrical component or module is knowledge about the hardware and software used to perform a diagnostic scan of a vehicle. If the vehicle manufacturer's vehicle communication interface, diagnostic software, or diagnostic procedures are used instead of those produced by a different entity, the reusability of an electrical component is likely greater than it would be if different vehicle communication interface diagnostic software, or diagnostic producers are used because the accountability, accuracy, completeness, administrative efficiency, or up-to-date maintenance is likely greater.

An additional example of additional information available for judging the reusability of an electrical component or module is knowledge about the reusability of electrical components similar to the first electrical component and currently or formerly installed in another motor vehicle. For example, if similar electrical components have been harvested from a vehicle and successfully reused in a different vehicle, then it may be inferred that the likelihood of the particular electrical component or module being capable of reuse is greater.

Yet another example of additional information available is knowledge from prior diagnostic heath scans. Take the case where there is a diagnostic trouble code for the Adaptive Cruise Control circuit or system and the corresponding diagnostic procedure indicates the Adaptive Cruise Control Sensor (a component Adaptive Cruise Control circuit or system) might need replacing or it might need reconfiguring or programming as a result of power loss. If a past diagnostic health scan occurred before the current diagnostic health scan and the past diagnostic health scan did not have a diagnostic trouble code and the damage location is not the same as the location of the Adaptive Cruise Control Sensor, then it is more likely the component needs reconfiguring or programming instead of replacement, thereby affecting the component's reusability.

A further example of additional information for determining the reusability of an electrical component or module is other DTCs on a current diagnostic health scan. For example, if there is an Adaptive Cruise Control circuit or system having a diagnostic trouble code, but other circuits or systems also have diagnostic trouble codes and there is a common point for these circuits or systems and the Adaptive Cruise Control circuit or system, such as a connector at a harness junction point, an inference or determination of reusability may be made. For example, it is more likely that a connector at a harness junction point is damaged than the Adaptive Cruise Control Sensor is damaged, thereby indicating potential reusability of the Adaptive Cruise Control Sensor.

Another example of additional information for determining or judging the reusability of an electrical component or module is a photograph of the vehicle, such as a photograph of the vehicle's dashboard warning lights. A circuit or system may have a DTC related to data communication, and the corresponding diagnostic procedure might require replacing a component and might require repairing wiring. The dashboard has no warning light indicating the component has malfunctioned. Based on information in such a photograph, it may be determined that it is more likely the wiring needs repairing instead of replacing the component, thereby indicating potential reusability of the component.

In an additional example, if a diagnostic health scan finds no DTCs for a circuit or system, the knowledge that there are no DTCs may be used to determine or grade the reusability of the various electrical components of the circuit or system.

In another example, a diagnostic health scan may find no DTCs for a circuit or system and may also find that there are no DTCs stored. Instead, it may find a different response, such as “no communication.” The knowledge there is no available information about the health of the circuit or system of a vehicle may be used to grade the reusability of the electrical components of the circuit or system.

In a further example, there may be a DTC and a corresponding diagnostic procedure for the DTC includes a task to replace a first electrical component (contingent upon the outcome of a test, verification, validation, or other task) but no task to replace a second electric component (contingent upon the outcome of a test, verification, validation, or other task). This knowledge may be used to grade the reusability of the first electrical component.

Of note is that the information in the above examples may be available remotely from the vehicle itself, e.g., a photograph of the vehicle may be transmitted to a remote location, the diagnostic health scan report or results may be transmitted to a remote location, some information which may not originate from the vehicle may similarly be considered, and so forth.

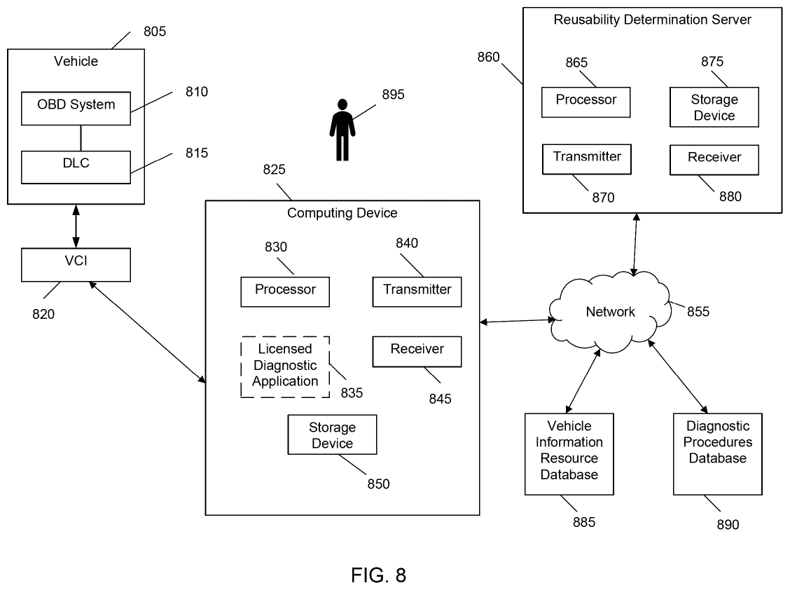

FIG. 8 illustrates an embodiment 800 of a system for determining the reusability of one or more electrical components or modules of a vehicle 805. A user 895, such as an automobile repair technician may utilize a computing device 825, such as a laptop computer, a desktop computer, a smart phone, smart tablet, or any other computing device capable of launching and running a licensed diagnostic application 835, such as an application specific to a certain vehicle manufacturer such as a General Motors, Ford, or Honda, to name just a few examples among many. For example, if vehicle 805 is a General Motors automobile, licensed diagnostic application 835 may be dedicated for use with General Motors automobiles. User 895 may provide one or more user inputs via licensed diagnostic application 835 to cause VCI 820 to provide a request for a diagnostic scan to an On-Board Diagnostic (OBD) system 810 via a DLC 815 of vehicle 805. Results of the requested diagnostics scan of vehicle 805 may be transmitted from OBD system 810 via DLC 815 and from VCI 820 to licensed diagnostic application 835. Licensed diagnostic application 835 may generate a diagnostic scan result, such as a file indicating results of the diagnostic scan of vehicle 805, and the diagnostic scan result may be stored in a storage device 850 of computing device 825. Although storage device 850 is illustrated as being internal to computing device 825, it should be appreciated that in some implementations, storage device 850 may be external to, but still accessible by, computing device 825.

Computing device 825 may include a processor 830, a transmitter 840, and a receiver 845. Processor 830 may execute instructions or program code stored in storage device 850, for example. Receiver 845 may receive messages or other communication transmitted to computing device 825, and transmitter 840 may transmit messages or other communication from computing device 825. Computing device 825 may be in communication with a reusability determination server 860 such as via a network 855, such as the Internet. Reusability determination server 860 may include a processor 865, a transmitter 870, a storage device 875, and a receiver 880, to name just a few potential components, among many, of reusability determination server 860. Reusability determination server 860 may receive a diagnostic scan result or report from computing device 825 for vehicle 805 and may attempt to grade or otherwise determine which electrical components or modules of vehicle 805 are likely in condition for harvesting from vehicle 805 and reuse in another vehicle. As discussed above, reusability determination server may make a determination of reusability based on a combination of information about vehicle 805 from computing device 825, as well as from other resources in some implementations, such as from vehicle information resource database 885 and/or diagnostic procedures database 890. Processor 865 of reusability determination server 860 may execute instructions or program code stored in storage device 875 to make such a determination, for example.

Vehicle information resource information database 885 may provide certain information relating to vehicle 805 to reusability determination server 860, such as photographs of vehicle 805. Such photographs may include photographs of a chassis or body, an engine block, or other photographs of the interior of the vehicle 8-5, such as of the dashboard or control panel thereof. Such photographs may show any warnings displayed on the dashboard or control panel, or other indications of damage to the vehicle 805, such as locations consistent with the vehicle 805 having been in an accident. Vehicle information resource database 885 may include additional information about vehicle 805, such as a previously performed diagnostic scan report or results, an identity of the current or previous owner(s) of the vehicle 805, a chain of custody of vehicle 805, whether a vehicle manufacturer's vehicle communication interface, diagnostic software, or diagnostic procedures have been used to perform a diagnostic health report or scan, to name just a few examples among many. Of course, additional sources of information may additionally or alternatively be considered, such as those discussed previously above.

Diagnostic procedures database 890 may include diagnostic procedures associated with various known DTCs. For example, such diagnostic procedures may be obtained from a vehicle's manufacturer. In accordance with an embodiment, if certain DTCs are determined from a diagnostic health scan or report for vehicle 805, a cross-reference may be made to corresponding diagnostic procedures stored in diagnostic procedures database 890 which are associated with those DTCs. Such associated diagnostic procedures may be obtained from diagnostic procedures database 890 and utilized by reusability determination server 860 to determine or grade a reusability of various electrical components or modules of vehicle 805.

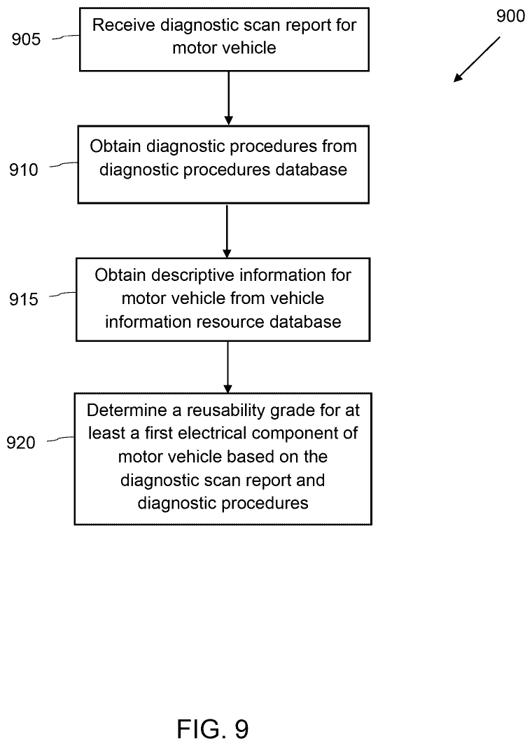

FIG. 9 illustrates an embodiment 900 of a flow diagram for grading the reusability of one or more electrical components for a motor vehicle. Embodiments in accordance with claimed subject matter may include all of, less than, or more than operations 905 through 920. Also, the order of operations 905 through 920 is merely an example order. For example, a method in accordance with embodiment 900 may be performed by a computing device having one or more processors.

At operation 905, a diagnostic scan report for the motor vehicle may be received, such as by a reusability determination server. The diagnostic scan report may indicate which motor vehicle systems or modules responded to a diagnostic scan request and any diagnostic trouble codes identified for any of the motor vehicle systems or modules.

At operation 910, diagnostic procedures may be obtained from a diagnostic procedures database. The diagnostic procedures may correspond to the diagnostic trouble codes identified in the diagnostic scan report. The diagnostic procedures may indicate an ordered series of operations for replacing at least a first electrical component of the motor vehicle corresponding to one of the diagnostic trouble codes identified in the diagnostic scan report contingent upon an outcome of a first task, verification, validation, or other first test on the at least a first electrical component of the motor vehicle.

At operation 915, descriptive information may be obtained for the motor vehicle from a vehicle information resource database. At operation 920, the reusability determination server may determine a reusability grade for the at least a first electrical component of the motor vehicle based on the diagnostic scan report, the diagnostic procedures, and the descriptive information. The determining may include assigning first relative weights to information from the diagnostic scan report, the diagnostic procedures, and the descriptive information. For example, in some implementations, a relatively higher weighting may be assigned to information obtained from the diagnostic scan report or from the diagnostic procedures, whereas a relatively lower weighting may be assigned to information contained in the descriptive information about the motor vehicle.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, semiconductor memory such as read-only memory (ROM), and/or any transmitting/receiving medium such as the Internet, cloud storage, the internet of things, or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

Some portions of the detailed description are presented herein in terms of algorithms or symbolic representations of operations on binary digital signals stored within a memory of a specific apparatus or special purpose computing device or platform. In the context of this particular specification, the term specific apparatus or the like includes a general-purpose computer once it is programmed to perform particular functions pursuant to instructions from program software. Algorithmic descriptions or symbolic representations are examples of techniques used by those of ordinary skill in the signal processing or related arts to convey the substance of their work to others skilled in the art. An algorithm is here, and generally, considered to be a self-consistent sequence of operations or similar signal processing leading to a desired result. In this context, operations or processing involve physical manipulation of physical quantities. Typically, although not necessarily, such quantities may take the form of electrical or magnetic signals capable of being stored, transferred, combined, compared or otherwise manipulated.

It has proven convenient at times, principally for reasons of common usage, to refer to such signals as bits, data, values, elements, symbols, characters, terms, numbers, numerals, files or the like. It should be understood, however, that all of these or similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a specific apparatus, such as a special purpose computer or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

It should be understood that for ease of description, a network device (also referred to as a networking device) may be embodied and/or described in terms of a computing device. However, it should further be understood that this description should in no way be construed that claimed subject matter is limited to one embodiment, such as a computing device and/or a network device, and, instead, may be embodied as a variety of devices or combinations thereof, including, for example, one or more illustrative examples.

The terms, “and”, “or”, “and/or” and/or similar terms, as used herein, include a variety of meanings that also are expected to depend at least in part upon the particular context in which such terms are used. Typically, “or” if used to associate a list, such as A, B or C, is intended to mean A, B, and C, here used in the inclusive sense, as well as A, B or C, here used in the exclusive sense. In addition, the term “one or more” and/or similar terms is used to describe any feature, structure, and/or characteristic in the singular and/or is also used to describe a plurality and/or some other combination of features, structures and/or characteristics. Likewise, the term “based on” and/or similar terms are understood as not necessarily intending to convey an exclusive set of factors, but to allow for existence of additional factors not necessarily expressly described. Of course, for all of the foregoing, particular context of description and/or usage provides helpful guidance regarding inferences to be drawn. It should be noted that the following description merely provides one or more illustrative examples and claimed subject matter is not limited to these one or more illustrative examples; however, again, particular context of description and/or usage provides helpful guidance regarding inferences to be drawn.

A network may also include now known, and/or to be later developed arrangements, derivatives, and/or improvements, including, for example, past, present and/or future mass storage, such as network attached storage (NAS), a storage area network (SAN), and/or other forms of computing and/or device readable media, for example. A network may include a portion of the Internet, one or more local area networks (LANs), one or more wide area networks (WANs), wire-line type connections, wireless type connections, other connections, or any combination thereof. Thus, a network may be worldwide in scope and/or extent. Likewise, sub-networks, such as may employ differing architectures and/or may be substantially compliant and/or substantially compatible with differing protocols, such as computing and/or communication protocols (e.g., network protocols), may interoperate within a larger network. In this context, the term sub-network and/or similar terms, if used, for example, with respect to a network, refers to the network and/or a part thereof. Sub-networks may also comprise links, such as physical links, connecting and/or coupling nodes, such as to be capable to transmit signal packets and/or frames between devices of particular nodes, including wired links, wireless links, or combinations thereof. Various types of devices, such as network devices and/or computing devices, may be made available so that device interoperability is enabled and/or, in at least some instances, may be transparent to the devices. In this context, the term transparent refers to devices, such as network devices and/or computing devices, communicating via a network in which the devices are able to communicate via intermediate devices of a node, but without the communicating devices necessarily specifying one or more intermediate devices of one or more nodes and/or may include communicating as if intermediate devices of intermediate nodes are not necessarily involved in communication transmissions. For example, a router may provide a link and/or connection between otherwise separate and/or independent LANs. In this context, a private network refers to a particular, limited set of network devices able to communicate with other network devices in the particular, limited set, such as via signal packet and/or frame transmissions, for example, without a need for re-routing and/or redirecting transmissions. A private network may comprise a stand-alone network; however, a private network may also comprise a subset of a larger network, such as, for example, without limitation, all or a portion of the Internet. Thus, for example, a private network “in the cloud” may refer to a private network that comprises a subset of the Internet, for example. Although signal packet and/or frame transmissions may employ intermediate devices of intermediate nodes to exchange signal packet and/or frame transmissions, those intermediate devices may not necessarily be included in the private network by not being a source or destination for one or more signal packet and/or frame transmissions, for example. It is understood in this context that a private network may provide outgoing network communications to devices not in the private network, but devices outside the private network may not necessarily be able to direct inbound network communications to devices included in the private network.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular examples disclosed, but that such claimed subject matter may also include all implementations falling within the scope of the appended claims, and equivalents thereof.

What is claimed is:

1. A process for determining the reusability of one or more electrical components of a motor vehicle, the process comprising:
receiving a diagnostic scan report for the motor vehicle, the diagnostic scan report indicating which motor vehicle systems or modules responded to a diagnostic scan request and any diagnostic trouble codes identified for any of the motor vehicle systems or modules;
obtaining diagnostic procedures from a diagnostic procedures database, the diagnostic procedures corresponding to the diagnostic trouble codes identified in the diagnostic scan report, the diagnostic procedures indicating an ordered series of operations for repairing or replacing at least a first electrical component of the motor vehicle corresponding to one of the diagnostic trouble codes identified in the diagnostic scan report contingent upon an outcome of a first task, verification, validation, or other first test on the at least a first electrical component of the motor vehicle; and
determining, by a reusability determination server, a reusability grade for the at least a first electrical component of the motor vehicle based on the diagnostic scan report and the diagnostic procedures, the determining including assigning first relative weights to information from the diagnostic scan report and the diagnostic procedures.

2. The process of claim 1, further comprising obtaining descriptive information for the motor vehicle from a vehicle information resource database.

3. The process of claim 2, wherein the descriptive information for the motor vehicle includes one or more of: photographs of the motor vehicle; previously performed diagnostic scan reports for the motor vehicle; an identity of the current or previous owner(s) of the motor vehicle; a chain of custody of the motor vehicle; an indication of whether a motor vehicle manufacturer's vehicle communication interface, diagnostic software, or diagnostic procedures were used to perform the diagnostic scan report; or a loss type, damage type, or physical event that occurred having potential of loss or harm to the motor vehicle.

4. The process of claim 1, further comprising transmitting the reusability grade for the at least a first electrical component of the motor vehicle to a user interface for display.

5. The process of claim 1, wherein the diagnostic procedures include an operation to replace a second electrical component that is different from the at least a first electrical component, the operation including performing a second test, verification, validation, or other second task; and
wherein the determining the reusability grade for the at least a first electrical component is further based on respectively locations within the motor vehicle of the at least a first electrical component, the second electrical component, and damage to the motor vehicle.

6. The process of claim 5, further comprising determining, by the reusability determination server, a reusability grade for the second electrical component of the motor vehicle based on the diagnostic scan report and the diagnostic procedures, the determining including assigning relative second weights to the information from the diagnostic scan report and the diagnostic procedures.

7. The process of claim 1, wherein the determining, by the reusability determination server, of the at least a first electrical component's reusability in another motor vehicle or elsewhere is based, at least partially, on an absence of the diagnostic trouble codes in the diagnostic scan report corresponding to the at least a first electrical component.

8. The process of claim 1, wherein the reusability grade for the at least a first electrical component is further based, at least in part, on at least one of a repair diagnostic scan or repair descriptive information about a secondary motor vehicle under repair.

9. A system comprising:
a reusability determination server having a processor to:
process a received diagnostic scan report for the motor vehicle, the diagnostic scan report indicating which motor vehicle systems or modules responded to a diagnostic scan request and any diagnostic trouble codes identified for any of the motor vehicle systems or modules;
obtain diagnostic procedures from a diagnostic procedures database, the diagnostic procedures corresponding to the diagnostic trouble codes identified in the diagnostic scan report, the diagnostic procedures indicating an ordered series of operations for repairing or replacing at least a first electrical component of the motor vehicle corresponding to one of the diagnostic trouble codes identified in the diagnostic scan report contingent upon an outcome of a first task, verification, validation, or other first test on the at least a first electrical component of the motor vehicle; and
determine a reusability grade for the at least a first electrical component of the motor vehicle based on the diagnostic scan report and the diagnostic procedures, the determining including assigning first relative weights to information from the diagnostic scan report and the diagnostic procedures.

10. The system of claim 9, wherein the processor is to further obtain descriptive information for the motor vehicle from a vehicle information resource database.

11. The system of claim 10, wherein the descriptive information for the motor vehicle includes one or more of: photographs of the motor vehicle; previously performed diagnostic scan reports for the motor vehicle; an identity of the current or previous owner(s) of the motor vehicle; a chain of custody of the motor vehicle; an indication of whether a motor vehicle manufacturer's vehicle communication interface, diagnostic software, or diagnostic procedures were used to perform the diagnostic scan report; or a loss type, damage type, or physical event that occurred having potential of loss or harm to the motor vehicle.

12. The system of claim 9, wherein the processor is to transmit the reusability grade for the at least a first electrical component of the motor vehicle to a user interface for display.

13. The system of claim 9, wherein the diagnostic procedures include an operation to replace a second electrical component that is different from the at least a first electrical component, the operation including performing a second test, verification, validation, or other second task; and
wherein the determining the reusability grade for the at least a first electrical component is further based on respectively locations within the motor vehicle of the at least a first electrical component, the second electrical component, and damage to the motor vehicle.

14. The system of claim 13, wherein the processor is to determine a reusability grade for the second electrical component of the motor vehicle based on the diagnostic scan report and the diagnostic procedures, the determining including assigning relative second weights to the information from the diagnostic scan report and the diagnostic procedures.

15. The system of claim 9, wherein the processor is to further determine the at least a first electrical component's reusability in another motor vehicle or elsewhere is based, at least partially, on an absence of the diagnostic trouble codes in the diagnostic scan report corresponding to the at least a first electrical component.

16. The system of claim 9, wherein the reusability grade for the at least a first electrical component is further based, at least in part, on at least one of a repair diagnostic scan or repair descriptive information about a secondary motor vehicle under repair.

17. An article, comprising:
a non-transitory storage medium comprising machine-readable instructions executable by a processor to perform a process for determining the reusability of one or more electrical components of a motor vehicle, the process comprising:
receiving a diagnostic scan report for the motor vehicle, the diagnostic scan report indicating which motor vehicle systems or modules responded to a diagnostic scan request and any diagnostic trouble codes identified for any of the motor vehicle systems or modules;
obtaining diagnostic procedures from a diagnostic procedures database, the diagnostic procedures corresponding to the diagnostic trouble codes identified in the diagnostic scan report, the diagnostic procedures indicating an ordered series of operations for repairing or replacing at least a first electrical component of the motor vehicle corresponding to one of the diagnostic trouble codes identified in the diagnostic scan report contingent upon an outcome of a first task, verification, validation, or other first test on the at least a first electrical component of the motor vehicle; and
determining a reusability grade for the at least a first electrical component of the motor vehicle based on the diagnostic scan report and the diagnostic procedures, the determining including assigning first relative weights to information from the diagnostic scan report and the diagnostic procedures.

18. The article of claim 17, wherein process for determining the reusability of one or more electrical components of a motor vehicle further comprises obtaining descriptive information for the motor vehicle from a vehicle information resource database.

19. The article of claim 18, wherein the descriptive information for the motor vehicle includes one or more of: photographs of the motor vehicle; previously performed diagnostic scan reports for the motor vehicle; an identity of the current or previous owner(s) of the motor vehicle; a chain of custody of the motor vehicle; an indication of whether a motor vehicle manufacturer's vehicle communication interface, diagnostic software, or diagnostic procedures were used to perform the diagnostic scan report; or a loss type, damage type, or physical event that occurred having potential of loss or harm to the motor vehicle.

20. The article of claim 17, wherein the machine-readable instructions are further executable by the processor to transmit the reusability grade for the at least a first electrical component of the motor vehicle to a user interface for display.

21. The article of claim 17, wherein the diagnostic procedures include an operation to replace a second electrical component that is different from the at least a first electrical component, the operation including performing a second test, verification, validation, or other second task; and
wherein the determining the reusability grade for the at least a first electrical component is further based on respectively locations within the motor vehicle of the at least a first electrical component, the second electrical component, and damage to the motor vehicle.

22. The article of claim 17, wherein the machine-readable instructions are further executable by the processor to further determine the at least a first electrical component's reusability in another motor vehicle or elsewhere is based, at least partially, on an absence of the diagnostic trouble codes in the diagnostic scan report corresponding to the at least a first electrical component.

23. The article of claim 17, wherein the reusability grade for the at least a first electrical component is further based, at least in part, on at least one of a repair diagnostic scan or repair descriptive information about a secondary motor vehicle under repair.
